(19) United States
(12) Patent Application Publication
(10) Pub. No.: US 2007/0247242 A1
(43) Pub. Date: Oct. 25, 2007

(54) QUADRATURE VOLTAGE-CONTROLLED OSCILLATOR

(75) Inventors: Jeong Hoon KIM, GYEONGGI-DO (KR); Sang-Gug LEE, DAEJEON (KR); Nam-Jin OH, DAEJEON (KR); Seok-Ju YUN, DAEJEON (KR); Eung Ju KIM, GYEONGGI-DO (KR); Tah Joon PARK, GYEONGGI-DO (KR)

Correspondence Address: LOWE HAUPTMAN HAM & BERNER, LLP, 1700 DIAGONAL ROAD, SUITE 300, ALEXANDRIA, VA, 22314, US

(73) Assignees: SAMSUNG ELECTRO-MECHANICS CO., LTD., GYUNGGI-DO (KR); RESEARCH AND INDUSTRIAL COOPERATION GROUP, DAEJEON (KR)

(21) Appl. No.: 11/733,042

(22) Filed: Apr. 9, 2007

(30) Foreign Application Priority Data
Apr. 10, 2006 (KR) 10-2006-0032514

(51) Int. Cl. H03L 7/085

(52) U.S. Cl. 331/1 A

(57) ABSTRACT

A quadrature voltage-controlled oscillator comprises a first delay cell outputting first and second phase signals having a different phase; and a second delay cell outputting third and fourth phase signals having a different phase, the third and fourth phase signals crossing the first and second phase signals, respectively. The first delay cell includes a first differential voltage-controlled oscillator connected to a power supply and outputting the first and second phase signals; and a first coupling section including first and second coupling transistors connected to the first differential voltage-controlled oscillator and first and second coupling capacitors connected in parallel to the first and second coupling transistors, respectively, so as to be grounded, the first coupling section coupling the output phase signals. The second delay cell includes a second differential voltage-controlled oscillator connected to the power supply and outputting the third and fourth phase signals; and a second coupling section including third and fourth coupling transistors connected to the second differential voltage-controlled oscillator and third and fourth coupling capacitors connected in parallel to the third and fourth coupling transistors, respectively, so as to be grounded, the second coupling section coupling the output phase signals.

### CROSS-REFERENCE TO RELATED APPLICATIONS

This application claims the benefit of Korean Patent Application No. 10-2006-0032514 filed with the Korea Intellectual Property Office on Apr. 10, 2006, the disclosure of which is incorporated herein by reference.

### BACKGROUND OF THE INVENTION

1. Field of the Invention

The present invention relates to a quadrature voltage-controlled oscillator having coupling capacitors, which can simultaneously enhance phase noise and phase error characteristics and can perform low-power oscillation.

2. Description of the Related Art

Quadrature voltage-controlled oscillators are circuits for generating four signals which have the same magnitude and of which the phases are delayed by 90 degrees from one another. Quadrature voltage-controlled oscillators are currently used in transceivers using a direct conversion method.

The direct conversion method is such a method that directly converts an RF (radio frequency) signal into a baseband signal. In the direct conversion method, the number of external elements such as filters can be reduced, and a burden on digital signal processing can be reduced. Therefore, researches on the method are being carried out actively.

As for a method where oscillation is performed by using four-phase signals in a general quadrature voltage-controlled oscillator, there are provided a frequency division method, where an oscillation frequency of single differential oscillator is divided by two so as to oscillate an I/Q signal, and a method where a 90-degree phase difference is achieved by a resistance capacitor (RC) and a poly phase filter.

In the former method, however, power consumption is large because of a high oscillation frequency. In the latter method, since passive elements are used, signal loss is so severe that an amplifier is needed at an output stage.

In order to solve the above-described problem, a quadrature coupling method is recently used, where signals oscillated by two independent differential oscillators are directly cross-coupled through a coupling transistor. Since this method has relatively low phase error and low power characteristics, the method is frequently applied when a RF transceiver requiring high performance is designed.

Circuit design methods where four phases are obtained through an existing quadrature coupling method will be examined as follows.

FIG. 1 is a block diagram schematically showing a quadrature voltage-controlled oscillator using a quadrature coupling method. As shown in FIG. 1, the quadrature voltage-controlled oscillator includes two delay cells 110 and 130 which are coupled to each other.

More specifically, signals output from negative (−) and positive (+) output stages of the first delay cell 110 are applied to positive and negative input stages of the second delay cell 130, respectively. Further, signals output from negative and positive output stage of the second delay cell 130 are applied to negative and positive input stages of the first delay cell 110, respectively.

In such a configuration, the negative and positive output stages of the first delay cell 110 output signals having the same magnitude and phases of 90 and 270 degrees, respectively. The positive and negative input stages of the second delay cell 130 output signals having the same magnitude and phases of 0 and 180 degrees, respectively.

FIG. 2 is a diagram illustrating a general structure of a radio transceiver including the quadrature voltage-controlled oscillator of FIG. 1.

FIG. 3 is a circuit diagram illustrating a conventional quadrature voltage-controlled oscillator. As shown in FIG. 3, the first and second delay cell 110 and 130 include differential voltage-controlled oscillators 310 and 330, respectively, which vary the frequency of an output signal by using a control voltage V_{ctrl}, and fifth to eighth NMOS transistors M₅ to M₈ connecting the first and second delay cells 110 and 130.

The fifth to eighth NMOS transistors M₅ to M₈ connect the respective outputs of the differential voltage-controlled oscillators 310 and 330. Among them, one pair is connected in parallel, but the other pair is cross-coupled.

Hereinafter, the connection among them and the operation thereof will be described.

The differential voltage-controlled oscillator 310 of the first delay cell 110 includes first and second NMOS transistors M₁ and M₂, first and second inductors L₁ and L₂, and first and second varactor Cᵥ₁ and Cᵥ₂. The differential voltage-controlled oscillator 330 of the second delay cell 130 includes third and fourth NMOS transistors M₃ and M₄, third and fourth inductors L₃ and L₄, and third and fourth varactor Cᵥ₃ and Cᵥ₄.

The first to fourth NMOS transistors M₁ to M₄ generate negative resistance of the differential voltage-controlled oscillators 310 and 330. The first and second NMOS transistors M₁ to M₂ are cross-coupled, and the third and fourth NMOS transistors M₃ and M₄ are cross-coupled.

The first to fourth inductors L₁ to L₄ and the first to fourth varactors Cᵥ₁ to Cᵥ₄ compose an LC tank. In accordance with a control voltage V_{ctrl} to be applied, the impedance of the LC tank is varied so that the frequency of an output signal is varied.

In the conventional voltage-controlled oscillator, each of the fifth to eighth NMOS transistors M₅ to M₈ serving as coupling transistors is connected in parallel between drain and source of each of the first to fourth NMOS transistors M₁ to M₄, as shown in FIG. 3. Specifically, the drains of the fifth to eighth NMOS transistors M₅ to M₈ are connected to the drains of the first to fourth NMOS transistors M₁ to M₄, respectively, and the sources of the fifth to eighth NMOS transistors M₅ to M₈ are connected to the sources of the first to fourth NMOS transistors M₁ to M₄, respectively.

The gates of the fifth and sixth NMOS transistors M₅ and M₆ of the first delay cell 110 respectively receive positive and negative output signals Q+ and Q− of the second delay cell 130, and the gates of the seventh and eighth NMOS transistors M₇ and M₈ of the second delay cell 130 respectively receive negative and positive output signals I− and I+ of the first delay cell 110.

The conventional quadrature voltage-controlled oscillator shown in FIG. 3 has an advantage of outputting four signals having the same magnitude and different phases from each other by using a relatively simple method.

FIG. 4 is a circuit diagram illustrating another conventional quadrature voltage-controlled oscillator. In the conventional quadrature voltage-controlled oscillator shown in FIG. 4, fifth to eighth NMOS transistors M₅ to M₈ serving as coupling transistors are serially connected to first and fourth NMOS transistors M₁ to M₄.

Specifically, the drains of the fifth to eighth NMOS transistors M₅ to M₈ are connected to an output stage, and the sources of the fifth to eighth NMOS transistors M₅ to M₈ are connected to the drains of the first and fourth NMOS transistors M₁ to M₄, respectively. Further, the gates of the fifth and sixth NMOS transistors M₅ and M₆ respectively receive positive and negative output signals Q+ and Q−of the second delay cell 130, and the gates of the seventh and eighth NMOS transistors M₇ and M₈ respectively receive negative and positive output signals I− and I+ of the first delay cell 110.

The conventional quadrature voltage-controlled oscillator shown in FIG. 4 has an advantage in that, as low-frequency noise signals generated by the fifth to eighth NMOS transistors M₅ to M₈ are transferred into two-times frequency of output signals, a phase noise characteristic is significantly enhanced.

FIG. 5 is a circuit diagram illustrating a further conventional quadrature voltage-controlled oscillator. As shown in FIG. 5, the conventional quadrature voltage-controlled oscillator includes first and second delay cells 110 and 130.

Hereinafter, the connection between them will be described in detail.

The first delay cell 110 includes a first differential voltage-controlled oscillator 510, first and second coupling transistors M₅ and M₆, and a tail current source I_{SS}. The first differential voltage-controlled oscillator 510 is connected between a power supply V_{DD} and the tail current source I_{SS}. In accordance with a control voltage V_{ctrl} to be applied, the first differential voltage-controlled oscillator 510 outputs a predetermined frequency of signal.

The drains of the first and second coupling transistors M₅ and M₆ are connected to the power supply V_{DD}, the sources of the first and second transistors M₅ and M₆ are connected to each other so as to be connected to the tail current source I_{SS}, and the gates of the first and second coupling transistors M₅ and M₆ respectively receive positive and negative output signals Q+ and Q− of the second delay cell 130.

The second delay cell 130 includes a second differential voltage-controlled oscillator 530, third and fourth coupling transistors M₇ and M₈, and a tail current source I_{SS}. The second differential voltage-controlled oscillator 530 is connected between a power supply V_{DD} and the tail current source I_{SS}. In accordance with a control voltage V_{ctrl} to be applied, the second differential voltage-controlled oscillator 530 outputs a predetermined frequency of signal.

The drains of the third and fourth coupling transistors M₇ and M₈ are connected to the power supply V_{DD}, the sources of the third and fourth coupling transistors M₇ and M₈ are connected to each other so as to be connected to the tail current source I_{SS}, and the gates of the third and fourth coupling transistors M₇ and M₈ respectively receive negative and positive output signals I− and I+ of the first delay cell 110.

In the quadrature voltage-controlled oscillator shown in FIG. 5, the drains of the coupling transistors M₅ to M₈ are directly connected to the power supply V_{DD} without inductors L of the differential voltage-controlled oscillators 510 and 530. Therefore, since the power supply V_{DD} at a high frequency are substantially the same as that in a ground state, frequency noise generated by the coupling transistors M₅ to M₈ is not transferred into an operation frequency. As a result, a phase noise characteristic is enhanced.

In the quadrature voltage-controlled oscillator shown in FIG. 3, low-frequency noise of the coupling transistor and unique noise of a switching transistor generating negative resistance are directly induced into the inductor of the LC tank so as to be transferred into an oscillation frequency. Therefore, a phase noise characteristic is greatly degraded.

The quadrature voltage-controlled oscillator shown in FIG. 4 has a relatively low phase error characteristic in comparison with an improved phase noise characteristic. Further, since the coupling transistor thereof is serially connected to a switching transistor, oscillation should be performed at high power.

The quadrature voltage-controlled oscillator shown in FIG. 5 has a low coupling characteristic. Therefore, a phase error characteristic is degraded.

### SUMMARY OF THE INVENTION

An advantage of the present invention is that it provides a quadrature voltage-controlled oscillator having coupling capacitors, which can simultaneously enhance phase noise and phase error characteristics and can enhance reception and transmission performance.

Another advantage of the invention is that it provides a quadrature voltage-controlled oscillator in which AC ground is formed by using a coupling capacitor so as to increase trans-conductance of a transistor. Therefore, the quadrature voltage-controlled oscillator can perform low-power oscillation.

Additional aspect and advantages of the present general inventive concept will be set forth in part in the description which follows and, in part, will be obvious from the description, or may be learned by practice of the general inventive concept.

According to an aspect of the invention, a quadrature voltage-controlled oscillator comprises a first delay cell outputting first and second phase signals having a different phase; and a second delay cell outputting third and fourth phase signals having a different phase, the third and fourth phase signals crossing the first and second phase signals, respectively. The first delay cell includes a first differential voltage-controlled oscillator connected to a power supply and outputting the first and second phase signals; and a first coupling section including first and second coupling transistors connected to the first differential voltage-controlled oscillator and first and second coupling capacitors connected in parallel to the first and second coupling transistors, respectively, so as to be grounded, the first coupling section coupling the output phase signals. The second delay cell includes a second differential voltage-controlled oscillator connected to the power supply and outputting the third and fourth phase signals; and a second coupling section including third and fourth coupling transistors connected to the second differential voltage-controlled oscillator and third and fourth coupling capacitors connected in parallel to the third and fourth coupling transistors, respectively, so as to be grounded, the second coupling section coupling the output phase signals.

According to another aspect of the invention, the first coupling section includes a first coupling transistor having a first terminal, a second terminal connected to the first differential voltage-controlled oscillator, and a third terminal connected to a ground terminal such that the magnitude and direction of current flowing from the second terminal to the third terminal are varied depending on the magnitude of the third phase signal applied to the first terminal; a second coupling transistor having a first terminal, a second terminal connected to the first differential voltage-controlled oscillator, and a third terminal connected to the ground terminal such that the magnitude and direction of current flowing from the second terminal to the third terminal are varied depending on the magnitude of the fourth phase signal applied to the first terminal; a first coupling capacitor connected in parallel to the first coupling transistor so as to be grounded; and a second coupling capacitor connected in parallel to the second coupling transistor so as to be grounded.

According to a further aspect of the invention, the first differential voltage-controlled oscillator includes a first transistor having a first terminal, a second terminal outputting the first phase signal, a third terminal connected to the second terminal of the first coupling transistor such that the magnitude and direction of current flowing from the second terminal to the third terminal are varied depending on a voltage applied to the first terminal; a second transistor having a first terminal connected to the second terminal of the first transistor, a second terminal connected to the first terminal of the first transistor so as to output the second phase signal, and a third terminal connected to the second terminal of the second coupling transistor such that the magnitude and direction of current flowing from the second terminal to the third terminal are varied depending on a voltage applied to the first terminal; and a first LC resonance circuit connected between the respective second terminals of the first and second transistors and the power supply.

According to a still further aspect of the invention, the first LC resonance circuit includes a first inductor connected between the power supply and the second terminal of the first transistor; a second inductor connected between the power supply and the second terminal of the second transistor; a first variable capacitor of which one end is connected to the second terminal of the first transistor and the other end receives a first control voltage for controlling the frequencies of the first and second phase signals to be output; and a second variable capacitor of which one end is connected to the second terminal of the second transistor and the other end receives a first control voltage for controlling the frequencies of the first and second phase signals to be output.

The first and second transistors and the first and second coupling transistors are MOS transistors, the first terminal is a gate, the second terminal is a drain, and the third terminal is a source. Further, the first and second variable capacitors are varactors.

According to a still further aspect of the invention, the second coupling section includes a third coupling transistor having a first terminal, a second terminal connected to the second differential voltage-controlled oscillator, and a third terminal connected to the ground terminal such that the magnitude and direction of current flowing from the second terminal to the third terminal are varied depending on the magnitude of the second phase signal applied to the first terminal; a fourth coupling transistor having a first terminal, a second terminal connected to the second differential voltage-controlled oscillator, and a third terminal connected to the ground terminal such that the magnitude and direction of current flowing from the second terminal to the third terminal are varied depending on the magnitude of the first phase signal applied to the first terminal; a third coupling capacitor connected in parallel to the third coupling transistor so as to be grounded; and a fourth coupling capacitor connected in parallel to the fourth coupling transistor so as to be grounded.

According to a still further aspect of the invention, the second differential voltage-controlled oscillator includes a third transistor having a first terminal, a second terminal outputting the third phase signal, a third terminal connected to the second terminal of the third coupling transistor such that the magnitude and direction of current flowing from the second terminal to the third terminal are varied depending on a voltage applied to the first terminal; a fourth transistor having a first terminal connected to the second terminal of the third transistor, a second terminal connected to the first terminal of the third transistor so as to output the fourth phase signal, and a third terminal connected to the second terminal of the fourth coupling transistor such that the magnitude and direction of current flowing from the second terminal to the third terminal are varied depending on a voltage applied to the first terminal; and a second LC resonance circuit connected between the respective second terminals of the third and fourth transistors and the power supply.

According to a still further aspect of the invention, the second LC resonance circuit includes a third inductor connected between the power supply and the second terminal of the third transistor; a fourth inductor connected between the power supply and the second terminal of the fourth transistor; a third variable capacitor of which one end is connected to the second terminal of the third transistor and the other end receives a second control voltage for controlling the frequencies of the third and fourth phase signals to be output; and a fourth variable capacitor of which one end is connected to the second terminal of the fourth transistor and the other end receives a second control voltage for controlling the frequencies of the third and fourth phase signals to be output.

The third and fourth transistors and the third and fourth coupling transistors are MOS transistors, the first terminal is a gate, the second terminal is a drain, and the third terminal is a source. Further, the third and fourth variable capacitors are varactors.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram schematically showing a quadrature voltage-controlled oscillator using a quadrature coupling method;

FIG. 2 is a diagram illustrating a general structure of a radio transceiver including the quadrature voltage-controlled oscillator of FIG. 1;

FIG. 3 is a circuit diagram illustrating a conventional quadrature voltage-controlled oscillator;

FIG. 4 is a circuit diagram illustrating another conventional quadrature voltage-controlled oscillator;

FIG. 5 is a circuit diagram illustrating a further conventional quadrature voltage-controlled oscillator;

FIG. 6 is a detailed circuit diagram of a quadrature voltage-controlled oscillator according to the present invention.

FIG. 7 is a partial circuit diagram of a coupling transistor according to the invention;

FIGS. 8A and 8B are graphs showing a current waveform at the x node of FIG. 7, FIG. 8A showing a current waveform when the coupling capacitor is not provided and FIG. 8B showing a current waveform when the coupling capacitor is provided;

FIG. 9 is a graph showing results of simulating phase noise characteristics of the conventional quadrature voltage-controlled oscillator shown in FIGS. 3 and 4 and the quadrature voltage-controlled oscillator of the invention; and

FIG. 10 is a graph showing results of simulating changes in phase noise and changes in phase error in accordance with coupling capacitor values of the invention.

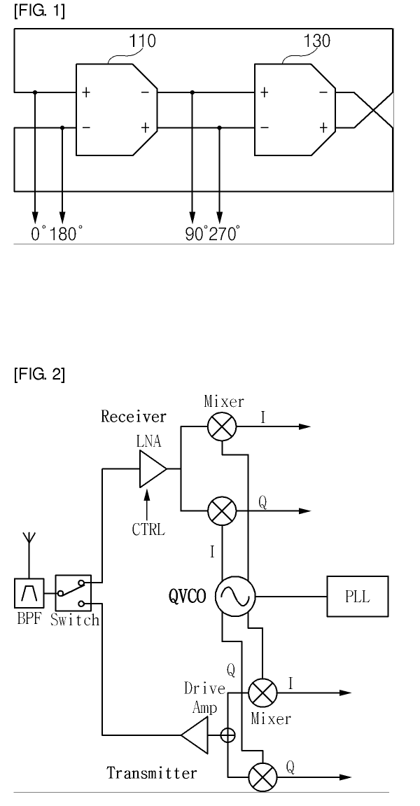

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a quadrature voltage controlled oscillator according to an embodiment of the present invention will be described in detail with reference to the accompanying drawings.

The quadrature voltage controlled oscillator uses eight active elements M_{S1} to M_{S4} and M_{C1} to M_{C4}. Each of the active elements includes a gate, a source, and a drain. The active elements have such a characteristic that, depending on the magnitude and polarity of a voltage applied between the gate and the source, the magnitude and direction of current are determined, the current flowing from the drain to the source or from the source to the drain.

As for such an active element, there are provided a bipolar junction transistor (BJT), a junction gate field-effect transistor (JFET), a metal-oxide-semiconductor field-effect transistor (MOSFET), a metal-semiconductor field-effect transistor (MESFET) and the like.

A certain active element further includes a body terminal in addition to a gate, a source, and a drain. Depending on the magnitude and polarity of a voltage applied between the gate and the body terminal, the quantity and direction of current are determined, the current flowing from the source to the drain or from the drain to the source. As for such an active element, there are provided a metal-oxide-semiconductor field-effect transistor (MOSFET) and the like.

The following descriptions will be focused on the MOSFET. However, the present invention can be applied to all active elements having the above-described characteristic as well as to the MOSFET. Therefore, although the descriptions are focused to the MOSFET, the scope of the invention is not limited to the MOSFET.

Further, the following descriptions will be focused on an embodiment using an n-type MOSFET, for convenience of description. However, the invention is not limited to a specific type of MOSFET. That is, a p-type MOSFET may be used, or both a p-type MOSFET and an n-type MOSFET may be used so as to perform substantially the same operation.

FIG. 6 is a detailed circuit diagram of the quadrature voltage-controlled oscillator according to the invention. As shown in FIG. 6, the quadrature voltage-controlled oscillator according to the invention includes first and second delay cells 610 and 630.

The first delay cell 610 outputs positive and negative in-phase signals I+ and I− having substantially the same magnitude and a phase difference of 90 degrees, and the second delay cell 630 outputs positive and negative quadrature-phase signals Q+ and Q− having substantially the same magnitude and a phase difference of 90 degrees.

As shown in FIG. 6, the first delay cell 610 and the second delay cell 630 are coupled to each other. The first delay cell 610 receives the output signals of the second delay cell 630, that is, third and fourth phase signals Q+ and Q−(which are positive and negative quadrature-phase signals, respectively). The second delay cell 630 receives the output signals of the first delay cell 610, that is, second and first phase signals I− and I+ (which are negative and positive in-phase signals, respectively).

The first delay cell 610 includes a first differential voltage-controlled oscillator 615 and a first coupling section 620.

The first differential voltage-controlled oscillator 615 is connected to a power supply V_{DD} and outputs the first and second phase signals I+ and I−.

The first coupling section 620 includes first and second coupling transistors M_{C1} and M_{C2}, connected to the first differential voltage-controlled oscillator 615, and first and second coupling capacitor C_{C1} and C_{C2} which are connected in parallel to the first and second coupling transistors M_{C1} and M_{C2}, respectively, so as to be grounded. The first coupling section 620 couples output phase signals I+, I−, Q+, and Q−.

The second delay cell 630 includes a second differential voltage-controlled oscillator 635 and a second coupling section 640.

The second differential voltage-controlled oscillator 635 is connected to the power supply V_{DD} and outputs the third and fourth phase signals Q+ and Q−.

The second coupling section 640 includes third and fourth coupling transistor M_{C3} and M_{C4}, connected to the second differential voltage-controlled oscillator 635, and third and fourth coupling capacitor C_{C3} and C_{C4} which are connected in parallel to the third and fourth coupling transistor M_{C3} and M_{C4}, respectively, so as to be grounded. The second coupling section 640 couples the output phase signals I+, I−, Q+, and Q−.

The first and second coupling sections 620 and 640 have a function of coupling output phase signals of both the differential voltage-controlled oscillators 615 and 635.

As shown in FIG. 6, the first and second coupling transistors M_{C1} and M_{C2} receive the third and fourth phase signals Q+ and Q−, respectively, and the third and fourth coupling transistors M_{C3} and M_{C4} receive the second and first phase signals I− and I+, respectively. Accordingly, between two outputs of the differential voltage-controlled oscillators 615 and 635, one is directly connected and the other is cross-connected by the first and second coupling sections 620 and 640. The first and second coupling sections 620 and 640 couples two of the differential voltage-controlled oscillators 615 and 635 such that the differential voltage-controlled oscillators 615 and 635 generate quadrature-phase signals I+, I−, Q+, and Q− having a phase difference of 90 degrees from one another.

Hereinafter, the connection among the components and the operation thereof will be described. In this case, the configuration of the second delay cell 630 is substantially the same as that of the first delay cell 610. Therefore, the following descriptions will be focused on the first delay cell 610.

The first coupling section 620 of the first delay cell 610 includes the first and second coupling transistors M_{C1} and M_{C2} and the first and second coupling capacitor C_{C1} and C_{C2}.

In the first coupling transistor M_{C1} the drain terminal thereof is connected to the first differential voltage-controlled oscillator 615, and the source terminal thereof is grounded. Further, the gate terminal thereof receives the third phase signal Q+ such that the magnitude and direction of current flowing from the drain terminal to the source terminal are varied in accordance with the magnitude of the third phase signal Q+.

In the second coupling transistor M_{C2}, the drain transistor thereof is connected to the first differential voltage-controlled oscillator 615, and the source terminal thereof is grounded. Further, the gate terminal thereof receives the fourth phase signal Q− such that the magnitude and direction of current flowing from the drain terminal to the source terminal are varied in accordance with the magnitude of the fourth phase signal Q−.

The first coupling capacitor C_{C1} is connected in parallel to the first coupling transistor M_{C1} so as to be grounded. The second coupling capacitor C_{C2} is connected in parallel to the second coupling transistor M_{C2} so as to be grounded.

As described above, the AC ground is provided by using the first and second coupling capacitors C_{C1} and C_{C2}, thereby increasing trans-conductance. Accordingly, the quadrature voltage-controlled oscillator according to the invention can perform low-power oscillation.

The first differential voltage-controlled oscillator 615 of the first delay cell 610 includes first and second transistors M_{S1} and M_{S2} and a first LC resonance circuit 625.

In the first transistor M_{S1}, the drain terminal thereof outputs the first phase signal I+, and the source terminal thereof is connected to the drain terminal of the first coupling transistor M_{C1}. Further, depending on a voltage applied to the gate terminal thereof, the magnitude and direction of current flowing from the drain terminal to the source terminal are varied.

In the second transistor M_{S2}, the gate terminal thereof is connected to the drain terminal of the first transistor M_{S1}, and the drain terminal thereof is connected to the gate terminal of the first transistor M_{S1}. Further, the drain terminal thereof outputs the second phase signal I−, and the source terminal is connected to the drain terminal of the second coupling transistor M_{S2}.

At this time, depending on a voltage applied to the gate terminal of the second transistor M_{S2}, the magnitude and direction of current flowing from the drain terminal to the source terminal are varied.

The first and second transistors M_{S1} and M_{S2} serve to generate negative resistance. The drain terminals and the gate terminals of the first and second transistors M_{S1} and M_{S2} are cross-coupled so that the generated negative resistance is provided to the first LC resonance circuit 625.

The first LC resonance circuit 625 includes first and second inductors L₁ and L₂ and first and second variable capacitors C_{V1} and C_{V2}. The inductors and the variable capacitors are caused to resonate with each other such that an oscillation signal is output.

At this time, the frequency of the oscillation signal is varied depending on the impedance of the first LC resonance circuit 625. The capacitances of the first and second variable capacitors C_{V1} and C_{V2} are varied by a first control voltage Vₜᵤₙₑ₁ such that the impedance of the first LC resonance circuit 625 is varied. Accordingly, since the frequency of an output signal can be changed, it is possible to control the frequency of the output signal.

The first inductor L₁ is connected between the power supply V_{DD} and the drain terminal of the first transistor M_{S1}, and the second inductor L₂ is connected to the power supply V_{DD} and the drain terminal of the second transistor M_{S2}.

In the first variable capacitor C_{V1}, one end thereof is connected to the drain terminal of the first transistor M_{S1}, and the other end thereof receives the first control voltage Vₜᵤₙₑ₁ for controlling the first and second phase output signals I+ and I−.

In the second variable capacitor C_{V2}, one end thereof is connected to the drain terminal of the second transistor M_{S2}, and the other end thereof receives the first control voltage Vₜᵤₙₑ₁ for controlling the first and second phase output signals I+ and I−.

As for the first and second variable capacitors C_{V1} and C_{V2}, a varicap diode, a varactor and the like can be used. Since the invention is used in wireless systems or various wired and wireless communication transceivers, the varactor suitable for a microwave band is preferably used.

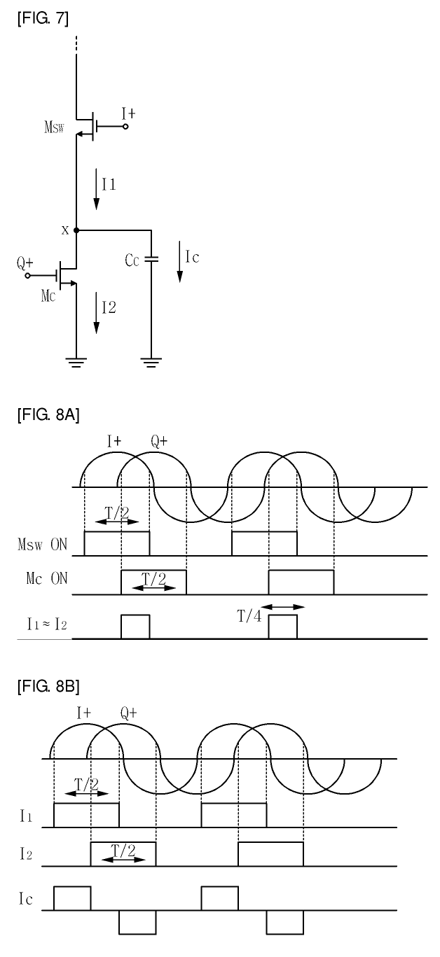

FIG. 7 is a partial circuit diagram of the coupling transistor according to the invention, showing a portion where a coupling capacitor C_{C} is connected in parallel to a coupling transistor M_{C} through a contact point x between a transistor M_{SW} and a coupling transistor M_{C}.

As shown in FIG. 7, the partial circuit of FIG. 7 receives output signals I+ and Q+ of the voltage-controlled oscillator through the transistor M_{SW} and the coupling transistor M_{C}, the output signals having a phase difference of 90 degrees. At this time, a current flowing through the transistor M_{SW} is referred to as I₁, a current flowing through the coupling transistor M_{C} is referred to as I₂, and a charging and discharging current flowing through the coupling capacitor C_{C} is referred to as I_{C}.

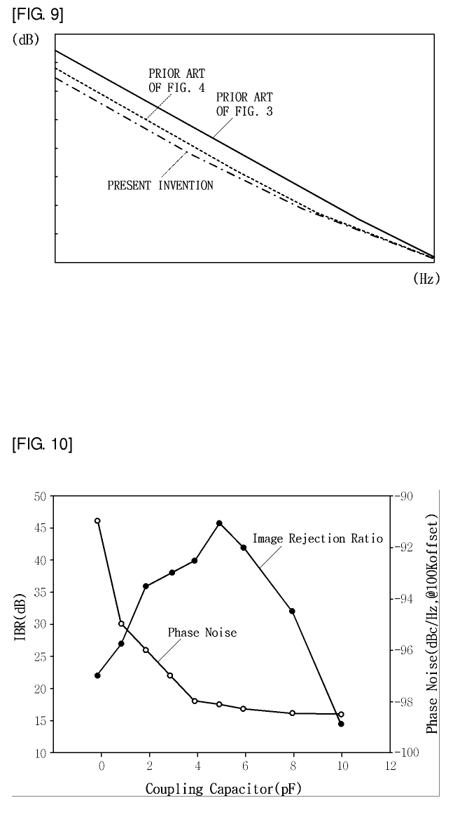

FIGS. 8A and 8B are graphs showing a current waveform at the x node of FIG. 7. FIG. 8A shows a current waveform when the coupling capacitor is not provided, and FIG. 8B shows a current waveform when the coupling capacitor is provided.

As shown in FIG. 8A, when the coupling capacitor C_{C} is not provided, the currents I₁ and I₂ are equalized. The currents can flow only when the transistor M_{SW} and the coupling transistor M_{C} are turned on at the same time. However, when the transistor M_{SW} and the coupling transistor M_{C} are not turned on at the same time, the currents inevitably flow into an arbitrary path, because the path of the currents is not formed. Therefore, the linearity of the transistor M_{SW} and the coupling transistor M_{C} is reduced.

When a period of an oscillation signal is set to T, a period of a current flow at the x node is reduced in half (T/2) such that a second harmonic component is strengthened. Accordingly, the non-linearity of the voltage-controlled oscillator increases as a whole.

Such an increase in non-linearity acts as a cause of significantly reducing a phase noise characteristic of the LC resonance circuit.

As shown in FIG. 7, however, if the coupling capacitor C_{C} is added to the contact point x between the transistor M_{SW} and the coupling transistor M_{C}, such a problem can be solved.

As shown in FIG. 8B, when the coupling capacitor C_{C} is added, and when only the transistor M_{SW} is turned on, the coupling capacitor C_{C} is charged with the current I₁. On the contrary, when only the coupling transistor M_{C} is turned on, discharge is performed by the coupling capacitor C_{C} charged with the current I₁ such that the current I₂ flows.

Therefore, in this embodiment where the coupling capacitor C_{C} is included, even when only one of two of the above-described transistors is turned on, an independent current path is formed. Accordingly, a switching operation by an oscillation frequency is smoothly performed, thereby preventing mutual interference through a harmonic wave. Therefore, low-frequency noises of the transistor M_{SW} and the coupling transistor M_{C} can be prevented from being transferred to the LC resonance circuit such that the non-linearity of the transistor can be improved. As a result, a phase noise characteristic can be also enhanced.

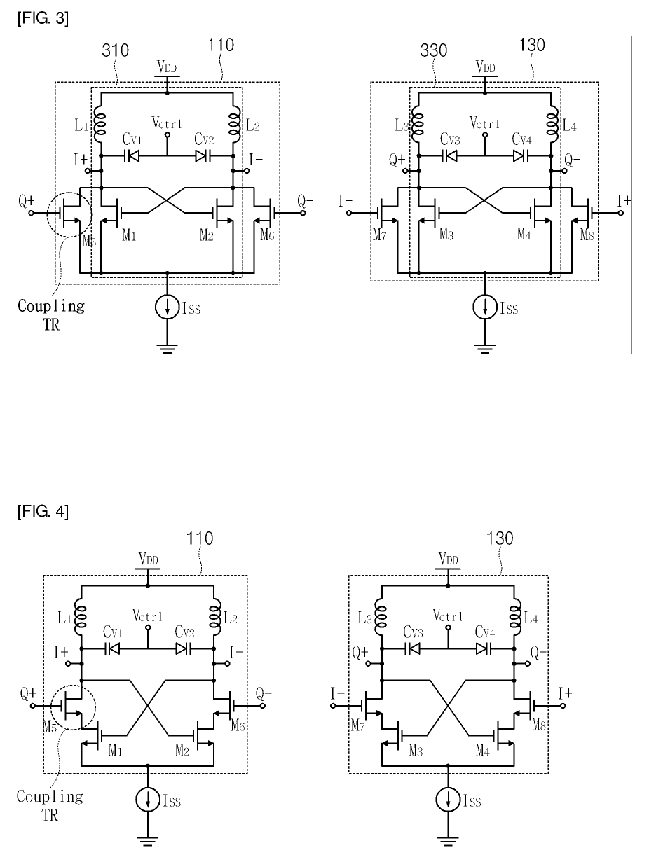

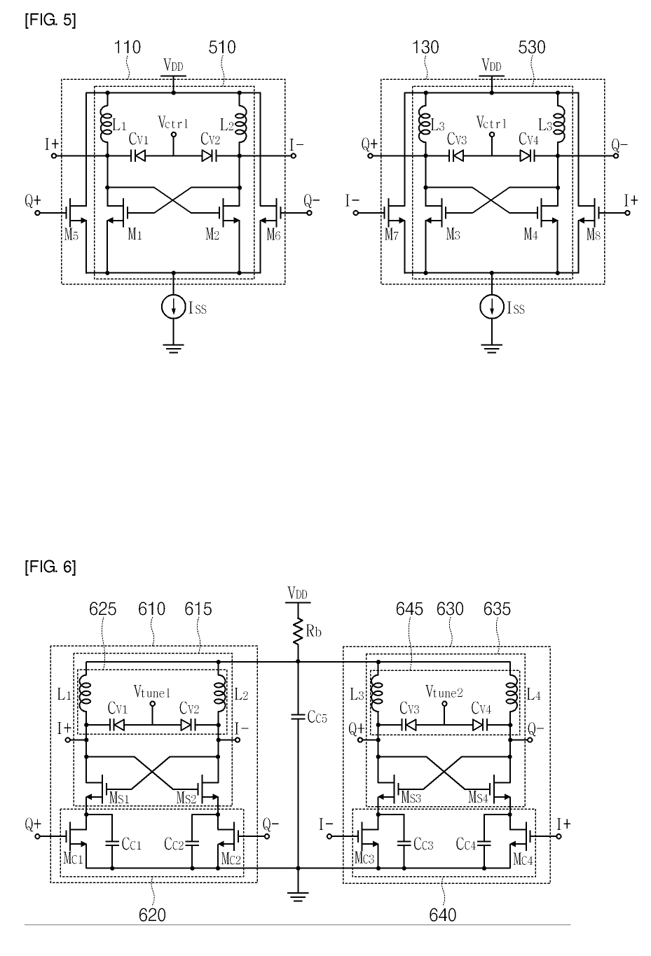

FIG. 9 is a graph showing results of simulating phase noise characteristics of the conventional quadrature voltage-controlled oscillator shown in FIGS. 3 and 4 and the quadrature voltage-controlled oscillator of the invention.

As shown in FIG. 9, it can be found that, when the quadrature voltage-controlled oscillator according to the invention includes the coupling capacitor, the quadrature voltage-controlled oscillator has more enhanced phase noise characteristics than the conventional quadrature voltage-controlled oscillator. However, since a phase noise characteristic and a phase error characteristic are generally in a trade-off relationship, it should be considered what effect the including of the coupling capacitor has on an phase error.

FIG. 10 is a graph showing results of simulating changes in phase noise and changes in phase error in accordance with coupling capacitor values of the invention.

Since the phase error characteristic is proportional to an image band rejection ratio, the phase error characteristic can be also represented by an image band rejection ratio. FIG. 10 shows that the changes in phase error are represented by change in image band rejection ratio.

As shown in FIG. 10, it can be found that, when a coupling capacitor having a capacitance of about 5 pF is included, the quadrature voltage-controlled oscillator has optimal phase noise and phase error characteristics.

Therefore, when a coupling capacitor having an optimal capacitance is selected and included in the invention, the phase noise and phase error characteristics can be improved at the same time.

The above descriptions can be proved by Equation 1.

$${G}_{mc} = \frac{{I}_{2}}{{V}_{q}^{+}} , m = \frac{{G}_{mc}}{{G}_{sw}} , d φ = Q \frac{d ω}{{m}^{2} {ω}_{osc}} \qquad [ Equation 1 ]$$

Here, G_{mc} represents trans-conductance, m represents coupling strength, and dφ represents a phase error.

Since the coupling capacitor serves to form an independent path of current flowing in the coupling transistor, the coupling capacitor increases the trans-conductance G_{mc} of the coupling transistor. Accordingly, the coupling strength m increases in accordance with Equation 1.

As examined in Equation 1, the larger the coupling strength m, the smaller the phase error dφ. As a result, when the coupling capacitor is added, the overall phase error characteristic can be enhanced.

According to the quadrature voltage-controlled oscillator of the invention, the coupling capacitor is included, thereby improving the non-linearity of the transistor. Accordingly, it is also possible to enhance a phase noise characteristic.

Further, the coupling capacitor is included so that the coupling strength is increased. Accordingly, it is possible to simultaneously enhance a phase error characteristic and a phase error characteristic.

Further, the AC ground is provided by using the coupling capacitor such that the trans-conductance of the transistor can be increased. As a result, it is possible to perform low-power oscillation.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A quadrature voltage-controlled oscillator comprising:
a first delay cell outputting first and second phase signals having a different phase; and
a second delay cell outputting third and fourth phase signals having a different phase, the third and fourth phase signals crossing the first and second phase signals, respectively,
wherein the first delay cell includes:
a first differential voltage-controlled oscillator connected to a power supply and outputting the first and second phase signals; and
a first coupling section including first and second coupling transistors connected to the first differential voltage-controlled oscillator and first and second coupling capacitors connected in parallel to the first and second coupling transistors, respectively, so as to be grounded, the first coupling section coupling the output phase signals, and
the second delay cell includes:
a second differential voltage-controlled oscillator connected to the power supply and outputting the third and fourth phase signals; and
a second coupling section including third and fourth coupling transistors connected to the second differential voltage-controlled oscillator and third and fourth coupling capacitors connected in parallel to the third and fourth coupling transistors, respectively, so as to be grounded, the second coupling section coupling the output phase signals.

2. The quadrature voltage-controlled oscillator according to claim 1,
wherein the first coupling section includes:
a first coupling transistor having a first terminal, a second terminal connected to the first differential voltage-controlled oscillator, and a third terminal connected to a ground terminal such that the magnitude and direction of current flowing from the second terminal to the third terminal are varied depending on the magnitude of the third phase signal applied to the first terminal;
a second coupling transistor having a first terminal, a second terminal connected to the first differential voltage-controlled oscillator, and a third terminal connected to the ground terminal such that the magnitude and direction of current flowing from the second terminal to the third terminal are varied depending on the magnitude of the fourth phase signal applied to the first terminal;
a first coupling capacitor connected in parallel to the first coupling transistor so as to be grounded; and
a second coupling capacitor connected in parallel to the second coupling transistor so as to be grounded.

3. The quadrature voltage-controlled oscillator according to claim 2,
wherein the first differential voltage-controlled oscillator includes:
a first transistor having a first terminal, a second terminal outputting the first phase signal, a third terminal connected to the second terminal of the first coupling transistor such that the magnitude and direction of current flowing from the second terminal to the third terminal are varied depending on a voltage applied to the first terminal;
a second transistor having a first terminal connected to the second terminal of the first transistor, a second terminal connected to the first terminal of the first transistor so as to output the second phase signal, and a third terminal connected to the second terminal of the second coupling transistor such that the magnitude and direction of current flowing from the second terminal to the third terminal are varied depending on a voltage applied to the first terminal; and
a first LC resonance circuit connected between the respective second terminals of the first and second transistors and the power supply.

4. The quadrature voltage-controlled oscillator according to claim 3,
wherein the first LC resonance circuit includes:
a first inductor connected between the power supply and the second terminal of the first transistor;
a second inductor connected between the power supply and the second terminal of the second transistor;
a first variable capacitor of which one end is connected to the second terminal of the first transistor and the other end receives a first control voltage for controlling the frequencies of the first and second phase signals to be output; and
a second variable capacitor of which one end is connected to the second terminal of the second transistor and the other end receives a first control voltage for controlling the frequencies of the first and second phase signals to be output.

5. The quadrature voltage-controlled oscillator according to claim 1,
wherein the second coupling section includes:
a third coupling transistor having a first terminal, a second terminal connected to the second differential voltage-controlled oscillator, and a third terminal connected to the ground terminal such that the magnitude and direction of current flowing from the second terminal to the third terminal are varied depending on the magnitude of the second phase signal applied to the first terminal;
a fourth coupling transistor having a first terminal, a second terminal connected to the second differential voltage-controlled oscillator, and a third terminal connected to the ground terminal such that the magnitude and direction of current flowing from the second terminal to the third terminal are varied depending on the magnitude of the first phase signal applied to the first terminal;
a third coupling capacitor connected in parallel to the third coupling transistor so as to be grounded; and
a fourth coupling capacitor connected in parallel to the fourth coupling transistor so as to be grounded.

6. The quadrature voltage-controlled oscillator according to claim 5,
wherein the second differential voltage-controlled oscillator includes:
a third transistor having a first terminal, a second terminal outputting the third phase signal, a third terminal connected to the second terminal of the third coupling transistor such that the magnitude and direction of current flowing from the second terminal to the third terminal are varied depending on a voltage applied to the first terminal;
a fourth transistor having a first terminal connected to the second terminal of the third transistor, a second terminal connected to the first terminal of the third transistor so as to output the fourth phase signal, and a third terminal connected to the second terminal of the fourth coupling transistor such that the magnitude and direction of current flowing from the second terminal to the third terminal are varied depending on a voltage applied to the first terminal; and
a second LC resonance circuit connected between the respective second terminals of the third and fourth transistors and the power supply.

7. The quadrature voltage-controlled oscillator according to claim 6,
wherein the second LC resonance circuit includes:
a third inductor connected between the power supply and the second terminal of the third transistor;
a fourth inductor connected between the power supply and the second terminal of the fourth transistor;
a third variable capacitor of which one end is connected to the second terminal of the third transistor and the other end receives a second control voltage for controlling the frequencies of the third and fourth phase signals to be output; and
a fourth variable capacitor of which one end is connected to the second terminal of the fourth transistor and the other end receives a second control voltage for controlling the frequencies of the third and fourth phase signals to be output.

8. The quadrature voltage-controlled oscillator according to claim 4,
wherein the first and second transistors and the first and second coupling transistors are MOS transistors, the first terminal is a gate, the second terminal is a drain, and the third terminal is a source.

9. The quadrature voltage-controlled oscillator according to claim 4,
wherein the first and second variable capacitors are varactors.

10. The quadrature voltage-controlled oscillator according to claim 7,
wherein the third and fourth transistors and the third and fourth coupling transistors are MOS transistors, the first terminal is a gate, the second terminal is a drain, and the third terminal is a source.

11. The quadrature voltage-controlled oscillator according to claim 7,
wherein the third and fourth variable capacitors are varactors.
